(19) United States
(12) Patent Application Publication
(10) Pub. No.: US 2022/0275533 A1
(43) Pub. Date: Sep. 1, 2022

(54) NON-CONTACT POLISHING OF A CRYSTALLINE LAYER OR SUBSTRATE BY ION BEAM ETCHING

(71) Applicant: ECOLE POLYTECHNIQUE FEDERALE DE LAUSANNE (EPFL), Lausanne (CH)

(72) Inventors: Niels QUACK, Yverdon-Les-Bains (CH); Sichen MI, Ecublens VD (CH); Teodoro GRAZIOSI, Renens (CH); Adrien TOROS, Le Mont sur Lausanne (CH)

(21) Appl. No.: 17/263,352

(22) PCT Filed: Jul. 26, 2019
(86) PCT No.: PCT/IB2019/056387

§ 371 Date: Jan. 26, 2021

(30) Foreign Application Priority Data
Jul. 27, 2018 (IB) PCT/IB2018/055622

(51) Int. Cl. C30B 33/12; H01J 37/305; C30B 29/04

(52) U.S. Cl. CPC C30B 33/12; H01J 37/3053; C30B 29/04; H01J 2237/3174

(57) ABSTRACT

Polishing method comprising the steps of: —providing at least one crystalline layer or substrate, the at least one crystalline layer or substrate extending in at least one plane, and including at least one outer surface and at least one depression extending from the at least one outer surface; and —polishing the at least one outer surface using ion beam etching (IBE) or an accelerated inert gas ion beam, the ion beam being incident on the at least one outer surface at non-normal incidence or at a non-zero angle (θ) with respect to the surface normal of the at least one plane of the crystalline layer or substrate.

### CROSS-REFERENCE TO RELATED APPLICATIONS

The present application claims priority to international patent application PCT/IB2018/055622 filed on Jul. 27, 2018, the entire contents thereof being herewith incorporated by reference.

### FIELD OF THE INVENTION

The present invention concerns polishing of a crystalline layer or a crystalline substrate and, in particular, polishing an outer surface of a crystalline layer or a crystalline substrate using ion beam etching (IBE) or an accelerated inert gas ion beam.

### BACKGROUND

Crystalline material such as Single Crystal Diamond has for long drawn interest in scientific and engineering research, owing to its outstanding material properties¹, including the highest thermal conductivity and mechanical hardness of any known bulk material, ultra-wide optical transparency, as well as extraordinary resistance to various chemicals. In addition, recently revealed quantum characteristics of diamond lattice defects have made it particularly appealing for atomic level sensing² and quantum information processing³. Recent advances in Chemical Vapour Deposition (CVD), have recently led to the availability of high purity synthetic single crystal diamond. Several suppliers offer nowadays high purity synthetic single crystal diamond substrates as polished platelets of several square millimeters in size and hundreds of microns in thickness, which suggests that single crystal diamond may serve as an ideal material platform for large scale nanophotonic applications.

However, the hardness and chemical inertness of diamond make it extremely difficult to process. Various techniques have been developed to achieve substrate preparation, and meanwhile allow preserving excellent material quality⁴⁻⁸. Among the traditional processing methods, mechanical surface polishing, studied over centuries⁹, continues to serve as the principal substrate preparation method⁹, and is still being actively investigated for further cost reduction¹⁰ and, most importantly, to improve device performance¹¹.

An Atomic Force Microscope (AFM) measurement of a typical mechanically polished surface of a (100) single crystal diamond (SCD) substrate is shown in FIG. 1A. Abundant scratches and polishing lines are found on the as-received sample purchased from Element Six (general grade, 2.6 mm×2.6 mm×0.5 mm). The AFM measurement reveals areas with relatively smooth surface, indicates 2-3° A surface roughness (Ra) over XYZ mm². This residual roughness can be attributed to the presence of typical polishing lines. However, the recording also reveals individual scratches, which are distributed randomly over the surface of the diamond substrate, featuring depths of up to 330 nm. Such scratches on the surface are, however, prohibiting large scale optoelectronic applications.

Recently, several non-contact polishing methods have been shown to be useful for smoothening the polishing lines without inducing further damages, including dressed-photon-phonon etching^{12,13,} reactive ion etching (RIE) with specific recipes^{14,15}, and normal-incidence ion beam etching (IBE)^{16,17}, However, these methods are not suitable for removing deep scratches, and as a consequence, a time-consuming fine polishing step remains nowadays the prevalent surface preparation method.

With the requirements for precision engineering and miniaturization of optoelectronic devices, developing efficient polishing techniques for hard and brittle materials such as for example diamond is of great importance and practical value.

### SUMMARY OF THE INVENTION

The present disclosure addresses the above-mentioned limitations by providing a polishing method according to claim 1.

The polishing method comprises the steps of:
providing at least one crystalline layer or substrate, the at least one crystalline layer or substrate extending in at least one plane, and including at least one outer surface and at least one depression extending from the at least one outer surface; and
polishing the at least one outer surface using ion beam etching or an accelerated inert gas ion beam, the ion beam being incident on the at least one outer surface at non-normal incidence or at a non-zero angle θ with respect to the surface normal of the at least one plane of the crystalline layer or substrate.

Other advantageous features can be found in the dependent claims.

In this disclosure, the Inventors present a non-contact surface polishing method based on ion beam etching or an accelerated inert gas ion beam etching with for example simultaneous sample rotation, which is fast and circumvents the difficulties associated with the surface preparation by fine polishing, notably the time-consuming removal of scratches on the layer or substrate surface, for example, a diamond surface, and/or the risk of fracture when the layer or substrate is very thin.

The Inventors demonstrate the effectiveness of the method by polishing exemplary single crystal diamond substrates.

By virtue of the rapid removal of surface damage and the simple implementation, the method of the present disclosure provides a path for cost-effective surface preparation of substrates, such as, for example, SCD for advanced nanophotonic and optoelectronic applications.

The method of the present disclosure advantageously provides a time-saving, inexpensive and uniform polishing method or process. Moreover, the polishing method of the present disclosure advantageously does not add or create new defects unlike other polishing methods such as mechanical polishing. The pressure applied to the substrate or layer under-going polishing is significantly less when compared to contact polishing. Polishing can be carried out at low pressure that is significantly lower than that experienced by the substrate during contact polishing. The polishing method is also advantageously a Fab-friendly etching process.

Another aspect of the present disclosure concerns a 3D structure production method.

The method comprises the steps of:
providing at least one crystalline layer or substrate, the at least one crystalline layer or substrate including at least one outer surface and at least one deposit or protrusion on the at least one outer surface; and
etching the at least one outer surface using ion beam etching or an accelerated inert gas ion beam, the ion beam being incident on the at least one outer surface at non-normal incidence or at a non-zero angle θ with respect to the surface normal of the at least one plane of the crystalline layer or substrate.

Other advantageous features can be found in the dependent claims.

The above and other objects, features and advantages of the present invention and the manner of realizing them will become more apparent, and the invention itself will best be understood from a study of the following description with reference to the attached drawings showing some preferred embodiments of the invention.

### A BRIEF DESCRIPTION OF THE SEVERAL VIEWS OF THE DRAWINGS

FIG. 1A shows an Atomic Force Microscope (AFM) measurement of a mechanically polished Single Crystal Diamond (SCD) substrate. Shallow polishing lines and deep scratches of various morphology are found. Inset: height profile along the lines A and B on the AFM picture, revealing typical scratch depths of up to 100 nm.

FIG. 1B is an exemplary schematic of the method of the present disclosure.

FIG. 2 shows Angle-dependent sputtering yield and material removal rate (normalized to normal incidence rate), based on reference data²⁰, and fitted with Eq. (1). Inset: schematic of a pit on the planar surface modeled as an inverse cone; θ and ϕ are polar and azimuthal angle of incident ion beam, respectively, and Ar+ indicates the incidence direction of the ion beam. The dashed line visualizes the generatrix of the inverted cone.

FIG. 3 shows the Etch rate on the generatrix in FIG. 2, as a function of etch depth and azimuthal rotation, simulated based on Eq. 1, with χ=0.4 and θ=60°. Angle-dependence of material removal rates is modelled with reference data represented with the solid curve in FIG. 2. Cut-off angle of 103° and cut-off depth of 37.52% at ϕ=0° are found. The cut-off depth varies with both ϕ and θ. Beyond cut-off there is no etching at all, as the ion beam is stopped at the planar surface. The model assumes invariance of the inversed cone geometry within one cycle of rotation. As etching continues, the pit shape changes slowly and this diagram will evolve accordingly.

FIG. 4A shows a sidewall etch rate relative to the planar top surface etch rate, averaged over ϕ∈[0,π). Cut-off only exists for χ<tan θ, and the critical depth d_{c} decreases as θ increases. Best selectivity is found at θ>θₘ.

FIG. 4B shows temporal evolution of the cross-section profile of a pit with h=100 nm and χ=0.4, simulated based on Eq. 1. Here θ is chosen at 60° and the pit depth is expected to be reduced to 2.4 nm in 514 seconds.

FIG. 5 shows a temporal evolution of an individual defect recorded by sequential Scanning Electron Microscope inspection, showing the rapid flattening of a typical defect after 20 min of surface treatment. Atomic Force Microscopy measurements confirmed reduction of the trench depth from 108 nm to 8 nm in 20 minutes. Further increasing surface polishing treatment time, no noticeable change was observed.

FIG. 6 shows a Scanning Electron Microscope recording showing nano-sized diamond particles remaining on the diamond surface after mechanical polishing. 4 minutes of 60° incidence-angle IBE with sample rotation yielded an increase in diameter for each of the four rounded bumps in the lower panel corresponding to a nano-diamond particle in the upper panel.

FIG. 7 compares structured diamond surfaces with (lower) and without (upper) the polishing method described in the present disclosure.

FIG. 8 shows the resulting polishing surface (right image) produced by the polishing method of the present disclosure when applied to the surface shown in the left image.

FIG. 9 shows upwardly extending curved surfaces on an outer surface of a layer or substrate that can be polished by the polishing method of the present disclosure.

The above and other objects, features and advantages of the present invention and the manner of realizing them will become more apparent, and the invention itself will best be understood from a study of the following description with reference to the attached drawings showing some preferred embodiments of the invention.

### DETAILED DESCRIPTION OF SEVERAL EMBODIMENTS

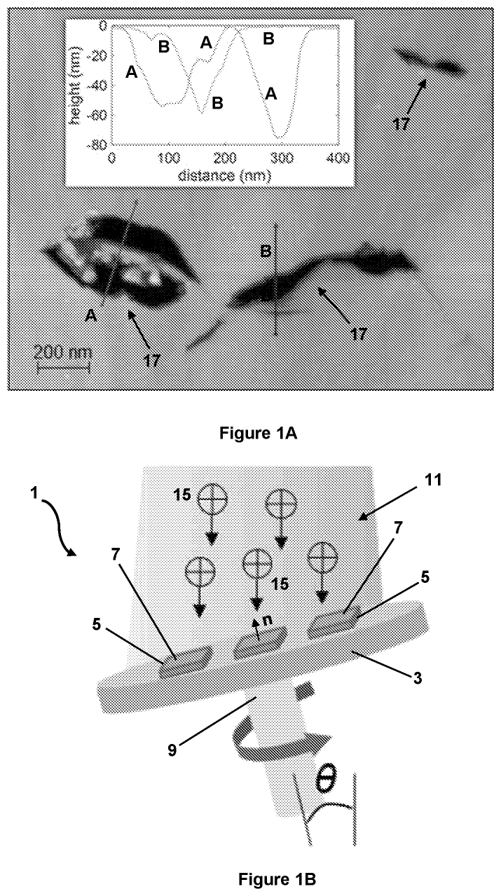

Ion Beam Etching is a well-known method for microstructuring and surface smoothening^{17,18}, using accelerated inert gas ions to bombard the material surface, causing curvature dependent erosion and mass redistribution¹⁹. Since the material removal is dominated by physical bombardment, ion beam etching is well suited for processing a large variety of materials¹⁸. However, when scratches (see FIG. 1) are present, ion beam etching with normal or near-normal incidence angle is no longer suitable for surface polishing, since such surface defects are not removed and under certain conditions are even exaggerated.

In contrast, the polishing method of the present disclosure takes into consideration the incidence-angle dependent variation of sputtering yield and sample rotation, and the ion beam etching process according to the present disclosure can be optimized for removal of scratches.

The Inventors propose a non-contact surface finishing of crystalline substrates or layers by ion beam etching and experimentally demonstrate the advantages of this present method via polishing of (100) single crystal diamond substrates. As detailed further below, the Inventors model and simulate the polishing process, and verify the results experimentally by monitoring individual defects during the surface treatment.

Rapid flattening of scratches and digs, as typically present on crystal substrates after mechanical polishing, is observed: trench depth is typically minimized by 95% in less than 30 minutes. The polishing method can exploit physical bombardment of the crystal surface with, for example, accelerated inert gas ions, rendering it highly versatile and applicable to a wide variety of crystalline materials.

FIG. 1B shows part of an exemplary system 1 for carrying out the polishing method of the present disclosure.

The system 1 includes a plate 3 configured for receiving and holding at least one or a plurality of layers or substrates 5 whose outer surface 7 is to be polished. The plate 3 is, for example, attached to a rotation shaft 9 permitting the plate 3 and the layers or substrates 5 to be rotated via a motor attached to the rotation shaft 9.

The system 1 includes an incident beam source configured to provide an etching beam 11 directed onto the plate 3 and the layers or substrates 5. The incident beam can, for example, include accelerated ions or accelerated inert gas ions 15.

The plate 3 and the rotation shaft 9 can be inclined with respect to the incident beam 11 permitting the incident beam 15 to be incident on the outer surface 7 at non-normal incidence or at a non-zero angle θ.

The system may further include, for example, a chamber inside which some or all of the above system elements are located.

The chamber defines an enclosure or closed space in which a specified or predetermined environmental condition can be set or defined. The chamber has a general function to confine or define an environment or a controlled environment with a specific property or properties. Such properties can be, for example, chemical composition or pressure. This controlled environment can be, for example, vacuum or gaseous. This controlled environment can also be or comprise a plasma environment.

The chamber is configured to define or control the environment in which the polishing method is carried out. The system 1 may further include one or more gauges for measuring parameter values such as, for example, a pressure inside the chamber. The chamber includes a port for inserting the layers or substrates 5 into the chamber and removing them therefrom.

The polishing method comprises providing at least one or a plurality of crystalline layer or substrate 5 for polishing.

The crystalline layer or substrate 5 may extend, for example, in a plane or define a planar structure. The crystalline layer or substrate 5 includes or defines the outer surface 7 to be polished.

The crystalline layer or substrate 5 may, for example, have a thickness t greater than 10 nm or 0.1 microns, for example, between 10 nm or 0.1 microns and 100 microns, or between 10 nm or 0.1 microns and 10 mm, or between 100 microns and 10 mm.

The crystalline layer or substrate 5 includes at least one or a plurality of valleys or depressions 17 (FIG. 1A) extending from the outer surface 7 internally inside the layer or substrate 5.

Polishing of the outer surface 7 is carried using ion beam etching (IBE) or an accelerated inert gas ion beam etching to eliminate or reduce the depth of the depression 17. Polishing is carried out by the ion beam being provided incident on the outer surface 7 at non-normal incidence or at a non-zero angle θ with respect to a surface normal n (vector perpendicular to a tangent plane of the outer surface 7) of the plane of the crystalline layer or substrate 5.

The ion beam 11 is, for example, incident on the outer surface 7 at non-normal incidence or at a non-zero angle with respect to the surface normal of the plane of the crystalline layer or substrate 5 to carry-out selective etching of the outer surface 7.

The ion beam 11 is, for example, incident on the outer surface 7 at non-normal incidence or at a non-zero angle with respect to the surface normal of the plane of the crystalline layer or substrate 5 to more quickly etch the outer surface 7 relative to or compared with the depression 17; or to provide a smaller material removal rate inside the depression 17 relative to depression-less area or areas of the outer surface 7.

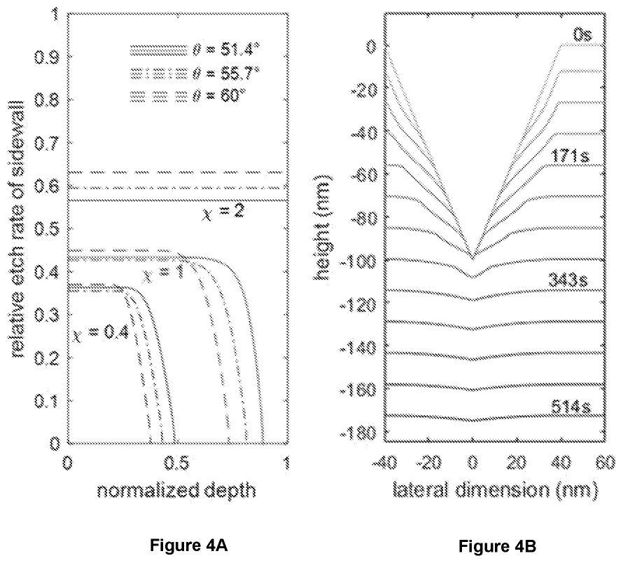

The non-normal incidence or oblique angle of incidence of the ion beam 11 produces an angle-dependent etch rate. Geometric shading from the ion beam 11 occurs inside depression 17 due to the non-normal incidence of the ion beam 11. As a result, the outer surface 7 is more quickly etched relative to the depression 17 permitting fast polishing of the of the crystalline layer or substrate 5, as can be seen in FIG. 4B.

The ion beam etching may, for example, comprise or consist of reactive ion beam etching.

The reactive ion beam etching may, for example, use oxygen reactive ion beam etching of the outer surface 7. This may, for example, be done using an Oxygen plasma. Chemical reaction with the crystalline layer or substrate 5 permits material removal. Acceleration of the oxygen ions towards to outer surface 7 may also be carried out to additionally remove material through physical impact or bombardment with the material of the crystalline layer or substrate 5.

The inert gas ion beam etching may, for example, include the acceleration of inert gas ions of Helium, or Neon, or Argon, or Krypton, or Xenon. These gases are non-chemically reacting with the crystalline layer or substrate 5 and instead remove material through physical impact or bombardment with the material of the crystalline layer or substrate 5.

The inert gas ion beam etching may be carried out, for example, with the crystalline layer or substrate 5 placed in an environment or atmosphere with the presence of gaseous species that is reactive to the materials to be polished, for example Oxygen or Hydrogen.

The crystalline layer or substrate 5 can be, for example, rotated during polishing. The crystalline layer or substrate 5 can be simultaneously rotated during ion beam etching of the crystalline layer or substrate 5. The crystalline layer or substrate 5 can be rotated, for example, at a value between 5 revolutions per minute (rpm) and 5000 rpm, for example, at 10 rpm.

The crystalline layer or substrate 5 can be, for example, a mechanically polished crystalline layer or substrate. The crystalline layer or substrate 5 can be, for example, a crystalline layer or substrate 5 that has previously undergone mechanical polishing prior to being polished using the polishing method of the present disclosure. Alternatively, the crystalline layer or substrate 5 can be, for example, a crystalline layer or substrate 5 including depression 17 similar to or equivalent to those produced by mechanical polishing.

Mechanical polishing includes processes such as grinding and/or buffing and/or lapping using, for example, abrasive media and/or buffing wheels.

In mechanical polishing the action on the material is mechanical, for example, a mechanical element directly or indirectly contacts the material to apply a downward pressure to permit material removal.

The crystalline layer or substrate 5 can be, for example, a chemical mechanically polished crystalline layer or substrate. The polishing action is, for example, partly mechanical and partly chemical. The mechanical element applies a downward pressure while the chemical reaction that takes place increases the material removal rate and is chosen to suit the type of material being processed.

The polishing step is, for example, a fine-polishing step.

Polishing can be carried out under an environmental pressure in the polishing chamber of between 1×10⁻³ mbar (0.1 Pa) to 1×10⁻⁵ mbar (0.001 Pa), or between 1×10⁻² mbar (1 Pa) to 1×10⁻⁶ mbar (0.0001 Pa), or between 1 mbar (100 Pa) to 1×10⁻⁷ mbar (0.00001 Pa).

The ions may be accelerated, for example, between 50 eV and 5000 eV and preferable between 300 eV and 1500 eV.

The crystalline layer or substrate 5 may comprise or consist solely of a hard and/or brittle material. The crystalline layer or substrate 5 may, for example, comprise or consist solely of a single crystal diamond (SCD) layer or substrate, or a synthetic single crystal diamond (SCD) layer or substrate. The crystalline layer or substrate 5 may, for example, alternatively comprise or consist solely of gallium nitride, or silicon carbide or at least one ceramic material such as, for example, Sapphire.

The crystalline substrate 5 may, for example, include a plurality of superposed layers where an outer layer of the superposed structure defines an outer surface 7 to be polished.

The depression or valley 17 is a defect in the surface of the crystalline layer or substrate 5 that is to be eliminated or reduced in depth. The depth of the depression 17 extends from the outer surface 7 in a direction into and/or inside the crystalline layer or substrate 5. The depression or valley 17 may, for example, define an arbitrary shape in the material of the crystalline layer or substrate 5.

The depression or valley 17 may, for example, comprise at least one or a plurality of sloping or curved side walls extending into the crystalline layer or substrate 5. The depression or valley 17 may, for example, comprise at least one or a plurality of floors. The at least one or the plurality of sloping or curved side walls may extend to the at least one or the plurality of floors.

The depression or valley 17 may, for example, include or consist solely of at least one scratch or trench or pit or polishing line (or a plurality thereof) extending from the outer surface 7 of the crystalline layer or substrate 5 inside the material of the crystalline layer or substrate 5.

The polishing is carried out to, for example, partially or fully remove, or flatten, or minimize the depth of the depression 17. For example, polishing is carried out to, for example, partially or fully remove, or flatten, or minimize the depth of the scratch, trench, pit or polishing line.

The depression 17 may have, for example, a depth between 25 nm and 10000 nm, or between 25 nm and 1000 nm, or between 50 nm and 500 nm, or between 75 nm and 400 nm, the extremity values of the above ranges being included.

The depression 17 may have, for example, a width W between 10 nm and 10000 nm, or between 10 nm and 1000 nm, or between 50 nm and 500 nm, or between 75 nm and 400 nm, the extremity values of the above ranges being included. The width W extends in a direction parallel to the planar direction or planar extension direction of the crystalline layer or substrate 5. The width W extends in a direction perpendicular to the depth of the depression 17 or a thickness t of the crystalline layer or substrate 5. The width W extends in a direction as shown by lines A or B in FIG. 1A.

The depression 17 is, for example, micron(μm)-sized or micron(μm)-dimensioned in depth and width W.

The depression 17 may, for example, define an aspect ratio value χ between 0.1 and 2, or between 0.4 and 1.2, or between 0.8 and 1.2, or between 0.9 and 1.1; or between 0.95 and 1.05; or between 0.4 and 1 where χ=(Width×0.5)/depth. This allows highly selective etching to be achieved.

The non-normal incidence or the non-zero angle θ can be defined or optimized according to the following sputtering yield equation:

$$Y ( E , θ ) ∝ \frac{E}{U {N ( 2 π A )}^{0.5}} exp ( - \frac{{cos}^{2} θ {a}^{2}}{2 A )} \qquad ( 1 )$$

wherein

angle θ is the ion beam 11 incidence compared to surface normal n,

A=cos² θα²+sin² θβ², with α being the energy range straggling along longitudinal direction and β being the energy range straggling along lateral direction, E the incident ion energy, a is the projected energy range, U the surface binding energy of atoms of the crystalline layer or substrate 5, and N the atomic density.

During ion bombardment the ions penetrate into the material surface and deposit energy alongside. The peak position for deposited energy is the projected energy range a, with the unit being the same with distance (such as nm).

The ion incident angle θ or ion beam incident angle θ can be, for example, between 10 degrees and 85 degrees, or between 20 and 85 degrees, or between 30 and 85 degrees, or between 30 and 80 degrees, or between 40 and 80 degrees, or between 45 and 75 degrees.

The non-normal incidence or the non-zero angle θ can be set, for example, at a value which is the same, or greater than or less than an angle θₘ at which a relative material removal rate MRR (normalized to the normal incidence rate) is highest. The non-normal incidence or the non-zero angle θ can be set at a value in the range of the angle θₘ±5°; or θₘ±10°; or θₘ±15°; or θₘ±20°. This allows high material removal and/or better selectivity to be achieved.

The relative material removal rate MRR (normalized to the normal incidence rate) can be calculated by multiplying the previously mentioned sputtering yield by cos θ.

The angles at which the ion sputtering yield and the relative material removal rate MRR (normalized to the normal incidence rate) is high is ion acceleration energy dependent, for example, a shift to higher angles occurs with increasing ion acceleration energy. Setting the non-normal incidence or the non-zero angle θ to a value in the range of the angle θₘ±5°; or θₘ±10°; or θₘ±15°; or θₘ±20° also provides a high material removal rate at increasing ion acceleration energy.

The non-normal incidence or the non-zero angle θ can be set, for example, at a value of the angle θₘ+5°; or θₘ+10°; or θₘ+15°; or θₘ+20°. This allows highly selective etching to be achieved. The non-normal incidence or the non-zero angle θ can be set at a value of the angle θₘ plus a positive integer multiple (1, 2, 3, 4 . . . ) of degrees up to and including 5°, or 10° or 15° or 20°.

As previously mentioned, the depression 17 may, for example, define an aspect ratio value χ between 0.4 and 1.2, or between 0.8 and 1.2, or between 0.9 and 1.1; or between 0.95 and 1.05; or between 0.4 and 1.

The crystalline layer or substrate 5 may be cleaned before polishing.

The polishing method of the present disclosure is, for example, a non-contact polishing method, or a non-mechanical polishing method.

The energy of the incident ions can for example be increased to increase etch selectivity.

The method of the present disclosure may further include a step of carrying out normal incidence ion beam polishing for smoothing of the outer surface 7. This step is carried out after the polishing steps described above are completed.

The method of the present disclosure may further include a step to remove an amorphous layer or material present on the crystalline layer or substrate 5. This can be done by applying, for example, an Oxygen plasma etching or through annealing. This step is carried out after the polishing steps described above are carried out.

The polishing method of the present disclosure may also be used in addition to other known polishing methods or techniques to render the polishing process even faster.

In an alternative embodiment of the present disclosure, the outer surface 7 of the layer or substrate 5 may alternatively or additionally comprise at least one or a plurality of upwardly or outwardly curved surfaces or zones 21 extending upwards or outwards from the surface 7 and the plane defined by the layer or substrate 5. The curved surfaces 21 may be dispersed at different locations across the outer surface 7. As shown schematically in FIG. 9, the curved surface(s) 21 extends outwards and defines an angle [3 of 10° or less (for example, between 10° and 0.1°) between its highest point HP and its lowest point LP (or the outer surface 7). The polishing method described above also permits the curved surfaces 21 to be polished.

In a further alternative embodiment of the present disclosure, the polishing method of the present disclosure may alternatively be used to polish a non-crystalline layer or substrate, for example, an amorphous or a polycrystalline layer or substrate. The amorphous or polycrystalline layer or substrate may, for example, have a thickness t greater than 10 nm or 0.1 microns, for example, between 10 nm or 0.1 microns and 100 microns, or between 10 nm or 0.1 microns and 10 mm, or between 100 microns and 10 mm.

The present disclosure also concerns a polished crystalline layer or substrate produced using the method of the present disclosure as well as a device including the polished crystalline layer or substrate.

As mentioned above, the polishing method of the present disclosure takes into consideration the incidence-angle dependent variation of sputtering yield and sample rotation, and the ion beam etching process according to the present disclosure can be optimized for removal of scratches.

The ion sputtering yield is defined as atoms removed by per incident ion, and exhibits an incidence-angle dependent behavior²¹, which is related to both material/ion properties and acceleration energy.

For example, the sputtering yield can be increased by >5× for 750 eV Ar⁺ impinging onto SCD at an ion beam incidence angle θ=60° compared to normal incidence. More generally, the angle depended sputtering yield can be described by²¹

$$Y ( E , θ ) ∝ \frac{E}{U {N ( 2 π A )}^{0.5}} exp ( - \frac{{cos}^{2} θ {a}^{2}}{2 A )} \qquad ( 1 )$$

where A=cos² θα²+sin² θβ², with α(β) being the energy range straggling along longitudinal (lateral) direction, E the ion energy, a the projected energy range, U the surface binding energy, and N the atomic density. Taking into account the flux dilution factor, the material removal rate can be further calculated by multiplying the sputtering yield by cos θ.

While this model was originally proposed to describe the angle-dependent sputtering yield for amorphous and polycrystalline materials, empirical data for single crystalline materials shows excellent agreement with the model²⁰, which can be attributed to the ion sputtering induced amorphization. Furthermore, molecular dynamics (MD) simulation on single crystal materials also confirmed good agreement with Eq. 1, although local maxima/minima can be present²², which, having negligible impact to the process described above, is believed to originate from the crystallographic nature.

The Inventors, for example, apply this model to typical scratches and pits on mechanically polished diamond crystal substrates. As the pit sidewalls exhibit a different angle with respect to the incident ions compared to the crystal platelet surface, they will be subjected to different material removal rates. With an appropriate parameter search, optimum conditions for ions hitting on the sidewall of a pit can be identified to have smaller material removal rate (MRR) than on the planar top surface, therefore leading to pit removal in a non-contact way.

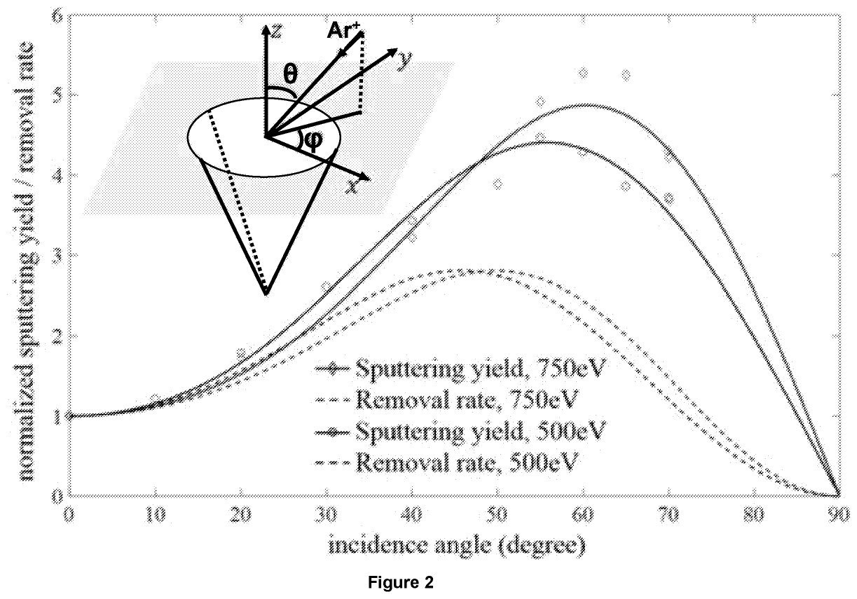

For example, for a (100) SCD substrate²⁰ treated by 750 eV Ark, the calculated maximum MRR normalised to that at normal incidence is 2.81, with ion incidence angle in the vicinity of θ=51.4° (denoted by θₘ), as illustrated in FIG. 2. Fitting parameters used here are α=34.28, β=43.39, and α=83.62. Exact values of other parameters are not relevant since we care for only the normalized results.

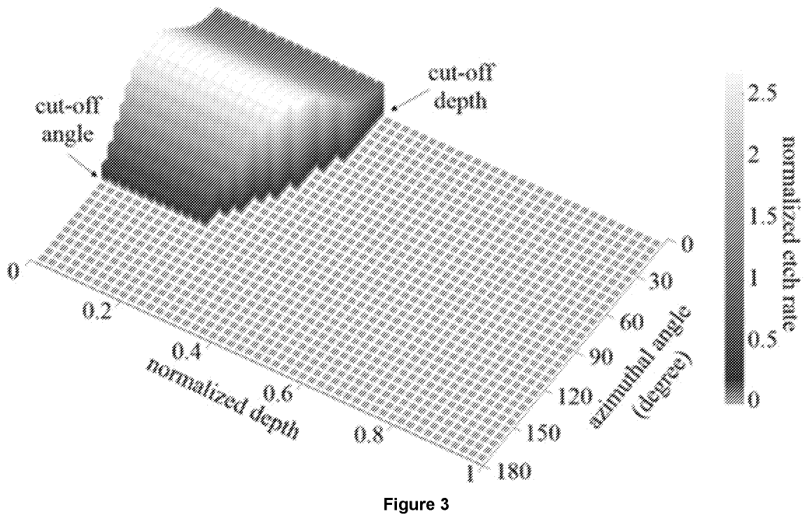

To illustrate the working principle of the process of the present disclosure, the Inventors model the surface pit as an inverse cone, as shown in FIG. 2, where ϕ and θ are the azimuthal and polar angle respectively of the incident ion beam. The Inventors further define χ≡r/h where r is the base radius and h depth, of the cone, indicating its sharpness. Due to the symmetry, one will only discuss the etching effect on the generatrix marked in FIG. 2. Without sample rotation during IBE, the pit will gradually become asymmetric; whereas with rotation, as the global incidence angle is being kept the same, the sidewall of the pit experiences local incidence angle variation depending on ϕ, which can give not only an averaged preferential etch on the top surface, but also a dynamical shading effect as long as χ<tan θ. This is illustrated in FIG. 3, where etch rate on the generatrix against azimuthal rotation and depth is simulated based on Eq. 1, assuming θ=60° and χ=0.4. The depth is normalized to 1 without loss of generality. The pit geometry is assumed to be invariant during one rotation cycle, which is reasonable as long as the etching rate is not too high, or the rotation speed is not too slow. It is worthwhile to note that the cut-off depth decreases with increasing ϕ, and no etching occurs for ϕ>103°, due to shading of the ion beam by the top surface.

The overall effect is a pit-depth depending material removal rate on the side wall: first, it is constant close to the planar top surface, and then with increasing depth it gradually decreases to zero, at the cut-off depth d_{c} at ϕ=0°. For any point deeper than d_{c}, there is no removal at all.

For crystalline materials, the material etch rate is typically dependent on the crystal plane orientation. However, considering that the IBE process amorphizes the surface during material removal²³, and considering that the pit sidewalls do not exhibit well-defined crystalline planes, it is reasonable to assume that this dependence can be neglected (cf. also discussion on experimental results). In the case of χ>tan θ, only the angle dependence of sputtering yield contributes to material removal. The planar top surface, on the other hand, is always under ion bombardment regardless of χ, with or without rotation. As shown in FIG. 4A, etch rate on the sidewall relative to that on the planar top surface (referred to as selectivity hereafter) at different depth is calculated with varying χ and θ, other parameters being the same as those used for FIG. 3. Similar to MRR, selectivity also remains constant over a certain depth, after which it gradually decreases to zero at d_{c}. However, due to local incidence-angle variation on the sidewall during rotation, best selectivity is not achieved at θₘ: as can be seen for the χ=1 and χ=0.4 cases in FIG. 4, a slightly higher θ gives better (smaller) selectivity. For χ=2>tan θ, no cut-off can be found. To provide a quantitative understanding of the working principle, an axisymmetric simulation was carried out, revealing the cross-section profile evolution in time during IBE treatment with sample rotation. The material removal rate on the planar top surface is set to 15 nm/min. In less than 9 minutes, the pit depth is reduced from 100 nm to 2.4 nm, for χ=0.4 and θ=60°.

To demonstrate the proposed non-contact polishing method, the SCD substrate shown in FIG. 1 was treated by IBE with sample rotation. In order to monitor individual pits on the diamond surface, first a ten by ten array of square-shaped plateaus is prepared on the substrate, each with 200 nm height and a side length of 10 μm. The exemplary fabrication process is as follows²⁴: after cleaning of the as-received sample with piranha solution, a silicon dioxide layer is deposited to protect the surface features, also acting as hard mask in subsequent etching; standard photo-lithography is used to pattern and develop spin-coated photo-resist, and the patterns are first transferred to the oxide layer, then to the diamond substrate with two steps of plasma etching, etching the unprotected oxide layer and diamond substrate respectively; finally the hard mask is completely removed by HF etching and the sample is cleaned with piranha once again to remove any residual contamination. Scanning Electron Microscopy (SEM) examination revealed at least two deep scratches on each plateau.

With this arrangement, individual surface scratches were monitored during a 28-minute IBE process with sample rotation at 10 rpm, using a Veeco Nexus IBE350 operating at 700 eV acceleration with Ar⁺ ion flux of 1.1 mA/cm². The Argon ion source used has an energy range from 300V to 700V, providing a flux from 0.52 to 1.14 mA/cm². Sample rotation was at 10 rpm. The incidence angle was set at 60° instead of θₘ as it gives smaller d_{c}. The vacuum level in the chamber was about 1×10⁻⁴ mbar.

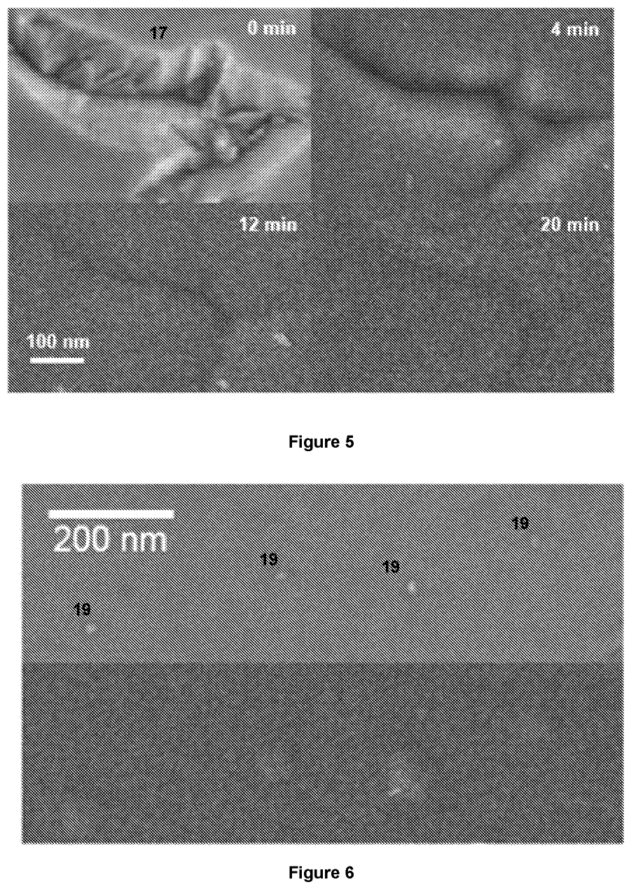

The temporal evolution of a single scratch was tracked by SEM before the IBE and after 4, 12, 20 minutes of treatment, as shown in FIG. 5. After 28 minutes of processing, the trench became too shallow to be found by SEM. AFM measurement confirmed trench depth reduction from 108 nm to 8 nm in 20 minutes. Other AFM measurements are listed in Table I.

TABLE I
Depth change of individual surface scratches before and
after 28 min of IBE treatment. The measurements reveal
increased polishing rate for narrower scratches (unit: nm)

| site | initial width | initial depth | finish depth |
|---|---|---|---|
| 1 | 330 | 140 | 7 |
| 2 | 196 | 93 | 3 |
| 3 | 120 | 70 | 3 |
| 4 | 120 | 66 | 3 |
| 5 | 250 | 160 | 10 |
| 6 | 590 | 330 | 40 |

In general, experimental parameters can be chosen according to Eq. 1 and empirical data can be taken into account to give optimal performance. Depending on processing purpose and surface characteristics, it is not always optimum to set the incidence angle to θₘ. Improved selectivity can be expected at higher acceleration voltages, which in the Inventors demonstration was limited to 700 eV by the instrument capabilities. While in the demonstration, the limited acceleration voltage yielded a maximum normalized material removal rate of 2.73 the IBE treatment with sample rotation allowed for rapid removal of deep scratches starting from a variety of initial conditions as listed in Table I.

According to yet another aspect, the present disclosure also concerns a 3D structure production method. At least one crystalline layer or substrate 5 is provided and at least one deposit or protrusion 19 is provided on the outer surface 7 of the crystalline layer or substrate 5.

Etching is carried out, as set out above, on the outer surface using ion beam etching IBE or an accelerated inert gas ion beam, with the ion beam being incident on the outer surface at non-normal incidence or at a non-zero angle θ with respect to the surface normal n of the plane of the crystalline layer or substrate 5.

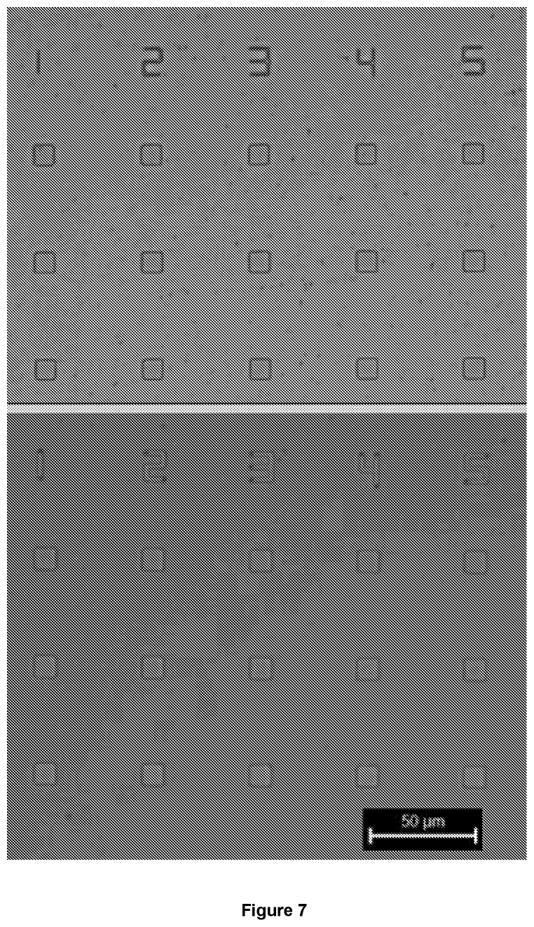

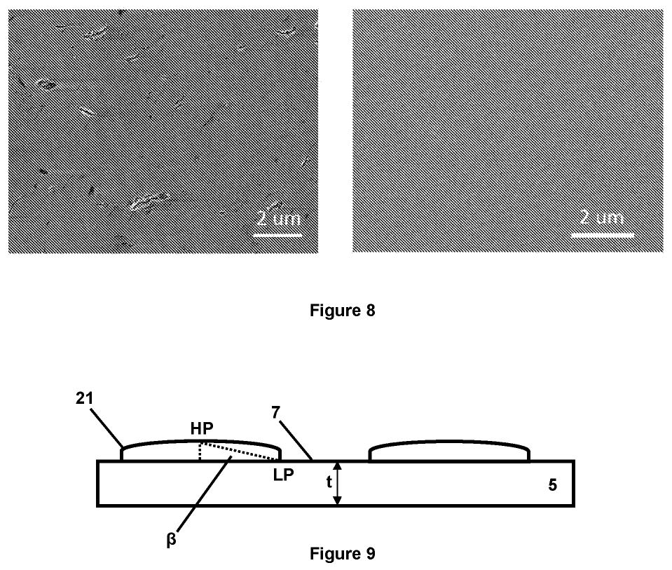

The Inventors observed, that while scratches can be readily removed by preferential etching of the planar top surface, however, protrudes or deposits on the surface tend to increase in width or diameter. The Inventors observe this effect experimentally in an area where diamond abrasives introduced in mechanical polishing were not completely removed. A comparison before and after 4 minutes of 60° incidence-angle IBE with sample rotation is shown in FIG. 6. This emphasizes the importance of thorough cleaning before using this method to polish surface, while at the same time indicates that 3D structures, e.g., micro-lenses or even bio-inspired compound eyes, can be fabricated following the same modeling.

The deposit or protrusion 19 defines a surface area smaller than a surface area defined by the outer surface 7.

Similar to the previously described polishing method, the ion beam is, for example, incident on the outer surface at non-normal incidence or at a non-zero angle with respect to the surface normal of the plane of the crystalline layer or substrate 5 to carry-out selective etching.

The crystalline layer or substrate 5 is preferably rotated during etching.

The crystalline layer or substrate 5 may comprise or consist solely of a hard and brittle material. The crystalline layer or substrate 5 may comprise or consist solely of a single crystal diamond (SCD) layer or substrate; or a synthetic single crystal diamond (SCD) layer or substrate.

The deposit or protrusion 19 may comprise or consist solely of a diamond abrasive.

The crystalline layer or substrate 5 may comprise or consist solely of gallium nitride, or silicon carbide. The deposit or protrusion 19 may comprise or consist solely of a gallium nitride, or silicon carbide abrasive.

The non-normal incidence or the non-zero angle θ is defined or optimized according to the previously mentioned sputtering yield equation (1).

The ion incident angle or ion beam incident angle can be, for example, between 10 degrees and 85 degrees, or between 20 and 85 degrees, or between 30 and 85 degrees, or between 30 and 80 degrees, or between 40 and 80 degrees, or between 45 and 75 degrees.

The present disclosure also concerns a 3D structure produced using the 3D structure production method.

The Inventors thus propose and demonstrate a versatile non-contact surface finishing method allowing rapid flattening of surface defects such as scratches and pits. The Inventors demonstrate the advantages of this method on, for example, Single Crystal Diamond substrates.

As the process is based on angle dependent sputtering yield and inert gas ions, the process is applicable and particularly advantageous to a wide range of existing and emerging material platforms such as gallium nitride, silicon carbide or various ceramics, where the final step of fine polishing typically requires dozens of hours or even more.

Since the process proposed relies on or exploits physical sputtering, it is a convenient way for surface treatment without the need to develop specific chemical recipes as typically required in alternative surface treatment methods such as chemical-mechanical polishing, RIE, etc.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims.

The features of any one of the above described embodiments may be included in any other embodiment described herein. When a range value is given, the range value includes the extremity values of the range.

### REFERENCES

¹ R. Mildren and J. Rabeau, Optical engineering of diamond (John Wiley & Sons, 2013).
² A. Ajoy, U. Bissbort, M. D. Lukin, R. L. Walsworth, and P. Cappellaro, Physical Review X 5, 011001 (2015).
³ M. J. Burek, C. Meuwly, R. E. Evans, M. K. Bhaskar, A. Sipahigil, S. Meesala, B. Machielse, D. D. Sukachev, C. T. Nguyen, J. L. Pacheco, et al., Physical Review Applied 8, 024026 (2017).
¹² M. Naruse, T. Yatsui, W. Nomura, T. Kawazoe, M. Aida, and M. Ohtsu, Applied Physics Letters 102, 071603 (2013).
¹³ T. Yatsui, W. Nomura, M. Naruse, and M. Ohtsu, Journal of Physics D: Applied Physics 45, 475302 (2012).
¹⁴ M. Challier, S. Sonusen, A. Barfuss, D. Rohner, D. Riedel, J. Koelbl, M. Ganzhorn, P. Appel, P. Maletinsky, and E. Neu, Micromachines 9, 148 (2018).
¹⁵ I. Friel, S. Clewes, H. Dhillon, N. Perkins, D. Twitchen, and G. Scarsbrook, Diamond and Related Materials 18, 808 (2009).
¹⁶ T. Nagase, H. Kato, S. Pahlovy, and I. Miyamoto, Journal of Vacuum Science & Technology B, Nanotechnology and Microelectronics: Materials, Processing, Measurement, and Phenomena 28, 263 (2010).
¹⁷ W. Liao, Y. Dai, Z. Liu, X. Xie, X. Nie, and M. Xu, Optics express 24, 4247 (2016).
¹⁸ F. Frost, R. Fechner, B. Ziberi, J. Vollner, D. Flamm, and A. Schindler, Journal of Physics: Condensed Matter 21, 224026 (2009).
¹⁹ C. S. Madi, E. Anzenberg, K. F. Ludwig Jr, and M. J. Aziz, Physical Review Letters 106, 066101 (2011).
²⁰ T. J. Whetten, A. A. Armstead, T. A. Grzybowski, and A. L. Ruoff, Journal of Vacuum Science & Technology A: Vacuum, Surfaces, and Films 2, 477 (1984).
²¹ Q. Wei, K.-D. Li, J. Lian, and L. Wang, Journal of Physics D: Applied Physics 41, 172002 (2008).
²² R. Smith and K. Beardmore, Thin Solid Films 272, 255 (1996).
²³ N. Kawasegi, S. Kuroda, N. Morita, K. Nishimura, M. Yamaguchi, and N. Takano, Diamond and Related Materials 70, 159 (2016).
²⁴ T. Graziosi, S. Mi, M. Kiss, and N. Quack, in Advances in Photonics of Quantum Computing, Memory, and Communication XI, Vol. 10547 (International Society for Optics and Photonics, 2018) p. 105470R.
²⁵ H. Hofsass, O. Bobes, and K. Zhang, Journal of Applied Physics 119, 035302 (2016).
²⁶ S. Mi, T. Graziosi, A. Toros, and N. Quack, manuscript accepted by The 29th International Conference on Diamond and Carbon Materials (2018).
²⁷ H. Deng, K. Endo, and K. Yamamura, Applied Physics Letters 107, 051602 (2015).
²⁸ H. Deng, K. Endo, and K. Yamamura, Applied Physics Letters 103, 111603 (2013).
²⁹ A. Esmaeilzare, A. Rahimi, and S. Rezaei, Applied Surface Science 313, 67 (2014).
³⁰ H. Aida, H. Takeda, S.-W. Kim, N. Aota, K. Koyama, T. Yamazaki, and T. Doi, Applied Surface Science 292, 531 (2014).
³¹ Hirata, A., Tokura, H., & Yoshikawa, M. (1992). Thin Solid Films, 212(1-2), 43-48.
³² Yoneda, K., Mameno, K., Kawahara, K., & Inoue, Y. (1990). U.S. Pat. No. 4,906,594.
³³ Deguchi, M., Yoshida, A., Kitabatake, M., & Hirao, T. (1998). U.S. Pat. No. 5,814,194.
³⁴ M. J. Burek, D. Ramos, P. Patel, I. W. Frank, and M. Lon\check{ }car, Applied Physics Letters 103, 131904 (2013).
³⁵ E. Neu, P. Appel, M. Ganzhorn, J. Miguel-S'anchez, M. Lesik, V. Mille, V. Jacques, A. Tallaire, J. Achard, and P. Maletinsky, Applied Physics Letters 104, 153108 (2014).
³⁶ A. Sipahigil, R. Evans, D. Sukachev, M. Burek, J. Borregaard, M. Bhaskar, C. Nguyen, J. Pacheco, H. Atikian, C. Meuwly, et al., Science, aah6875 (2016).
³⁷ M. Pomorski, B. Caylar, and P. Bergonzo, Applied Physics Letters 103, 112106 (2013).
³⁸ T. X. Zhou, R. J. S″ohr, and A. Yacoby, Applied Physics Letters 111, 163106 (2017).
³⁹ T. Schuelke and T. A. Grotjohn, Diamond and Related Materials 32, 17 (2013).
⁴⁰ W. Scalbert, D. Tanner, F. Laffir, and R. Holtz, in High-Power Laser Materials Processing: Applications, Diagnostics, and Systems VII, Vol. 10525 (International Society for Optics and Photonics, 2018) p. 105250N.
⁴¹ H. A. Atikian, A. Eftekharian, A. Jafari Salim, M. J. Burek, J. T. Choy, A. Hamed Majedi, and M. Lon\check{ }car, Applied Physics Letters 104, 122602 (2014).

The contents of each of the above references being fully incorporated herein by reference.

1-40. (canceled)

41. Polishing method comprising the steps of:
providing at least one crystalline layer or substrate, the at least one crystalline layer or substrate extending in at least one plane, and including at least one outer surface and at least one depression extending from the at least one outer surface; and
polishing the at least one outer surface using accelerated inert gas ion beam etching or ion beam etching, the ion beam being incident on the at least one outer surface at non-normal incidence or at a non-zero angle θ with respect to the surface normal of the at least one plane of the crystalline layer or substrate.

42. Method according to claim 41, wherein the ion beam is incident on the at least one outer surface at non-normal incidence or at a non-zero angle with respect to the surface normal of the at least one plane of the crystalline layer or substrate to carry-out selective etching of the at least one outer surface.

43. Method according to claim 41, wherein the ion beam is incident on the at least one outer surface at non-normal incidence or at a non-zero angle with respect to the surface normal of the at least one plane of the crystalline layer or substrate to more quickly etch the at least one outer surface relative to the at least one depression, or to provide a smaller material removal rate in the at least one depression relative to the at least one outer surface.

44. Method according to claim 41, wherein the at least one crystalline layer or substrate comprises or consists solely of a single crystal diamond layer or substrate; or a synthetic single crystal diamond layer or substrate.

45. Method according to claim 41, wherein the depression includes or consists solely of at least one scratch, trench, polishing line or pit extending from the at least one outer surface of the crystalline layer or substrate.

46. Method according to claim 41, wherein the polishing is carried out to partially or fully remove, or flatten, or minimize the at least one scratch or trench or polishing line or pit.

47. Method according to claim 41, wherein the non-normal incidence or the non-zero angle θ is defined or optimized according to the following sputtering yield equation:
$$Y ( E , θ ) ∝ \frac{E}{U {N ( 2 π A )}^{0.5}} exp ( - \frac{{cos}^{2} θ {a}^{2}}{2 A )}$$
wherein
angle θ is the ion beam incidence compared to surface normal,
A=cos² θα²+sin² θβ², with α being the energy range straggling along longitudinal direction and β being the energy range straggling along lateral direction, E the ion energy, a is the projected energy range, U the surface binding energy, and N the atomic density.

48. Method according to claim 41, wherein the ion incident angle or ion beam incident angle θ is between 10 degrees and 85 degrees.

49. Method according to claim 41, wherein the non-normal incidence or the non-zero angle θ is set at a value which is the same, different or greater than an angle θₘ at which a relative material removal rate is highest.

50. Method according to claim 49, wherein the relative material removal rate is determined by multiplying the sputtering yield by cos θ, θ being the non-normal incidence or the non-zero angle.

51. Method according to claim 49, wherein the non-normal incidence or the non-zero angle θ is set at a value in the range: angle θₘ±5°.

52. Method according to claim 41, wherein the depression defines an aspect ratio value between 0.4 and 1.2; where the aspect ratio value is defined by [width of the depression×0.5] divided by the depth of the depression.

53. Method according to claim 41, further including a step of cleaning the at least one crystalline layer or substrate before the polishing step.

54. Method according to claim 41, further including a step of increasing the energy of the ions to increase etch selectivity.

55. Method according to claim 41, wherein the ion beam etching is a reactive ion beam etching.

56. Method according to claim 41, wherein the outer surface of the layer or substrate comprises at least one or a plurality of upwardly or outwardly curved surfaces extending upwards or outwards from the outer surface, the at least one or the plurality of curved surfaces extend outwards and define an angle β of 10° or less between a highest point and a lowest point of the curved surface; and wherein the polishing step of the outer surface is applied to polish the at least one or a plurality of curved surfaces.

57. Method according to claim 41, further including a step of carrying out normal incidence ion beam polishing for smoothing of the outer surface.

58. Method according to claim 41, further including a step to remove an amorphous layer or material present on the crystalline layer or substrate.

59. 3D structure production method comprising the steps of:
providing at least one crystalline layer or substrate, the at least one crystalline layer or substrate including at least one outer surface and at least one deposit or protrusion on the at least one outer surface; and
etching the at least one outer surface using accelerated inert gas ion beam etching or ion beam etching, the ion beam being incident on the at least one outer surface at non-normal incidence or at a non-zero angle θ with respect to the surface normal of the at least one plane of the crystalline layer or substrate.

60. Method according to claim 59, wherein the non-normal incidence or the non-zero angle (θ) is defined or optimized according to the following sputtering yield equation:
$$Y ( E , θ ) ∝ \frac{E}{U {N ( 2 π A )}^{0.5}} exp ( - \frac{{cos}^{2} θ {a}^{2}}{2 A )}$$
wherein
angle θ is the ion beam incidence compared to surface normal,
A=cos² θα²+sin² θβ², with α being the energy range straggling along longitudinal direction and β being the energy range straggling along lateral direction, E the ion energy, a is the projected energy range, U the surface binding energy, and N the atomic density.
